(19) United States
(12) Patent Application Publication
(10) Pub. No.: US 2011/0254152 A1
(43) Pub. Date: Oct. 20, 2011

(54) CHIP STRUCTURE, CHIP BONDING STRUCTURE USING THE SAME, AND MANUFACTURING METHOD THEREOF

(76) Inventor: Ching-San Lin, Wufeng Township (TW)

(21) Appl. No.: 13/089,449

(22) Filed: Apr. 19, 2011

(30) Foreign Application Priority Data
Apr. 20, 2010 (TW) 099112291

(51) Int. Cl. H01L 23/498; H01L 21/60

(52) U.S. Cl. 257/737; 438/613; 257/E23.068; 257/E21.508

(57) ABSTRACT

An IC chip and an IC chip manufacturing method thereof are provided. The IC chip has a chip body and at least one bump. The chip body has at least one conducting area on its surface. The bump is formed on the conducting area of the chip body. The bump includes a plurality of protrusions and at least one conducting material. The protrusions protrude out of the conducting area and are spaced apart from each other. The conducting material covers the protrusions and electrically connects the conducting area. The method includes: (A) providing a chip body having a conducting area on its surface; (B) forming a plurality of protrusions on the chip body, wherein the protrusions protrude out of the conducting area and are spaced apart from each other; and (C) forming at least one conducting material, wherein the conducting material covers the protrusions and electrically connects the conducting area.

### CROSS-REFERENCE TO RELATED APPLICATION

This application claims priority based on Taiwanese Patent Application No. 099112291, filed on Apr. 20, 2010, the disclosure of which is incorporated herein by reference in its entirety.

### BACKGROUND OF THE INVENTION

1. Field of the Invention

The present invention generally relates to an integrated circuit chip and a manufacturing method thereof. More particularly, this invention relates to an integrated circuit chip for coupling to a circuit board and a manufacturing method thereof.

2. Description of the Prior Art

Conventional techniques of attaching the chip onto the circuit board generally utilize the wire-bonding method. However, because the wire-bonding technique does not satisfy the electric requirement, a process of employing conducting adhesives, such as anisotropic conductive film (ACF), to attach the chip onto the circuit board is developed.

As shown in FIG. 1, the conducting adhesive generally includes a plurality of conducting particles 21 and an insulating material 20. The cover film and the base film are respectively disposed on top and bottom sides of the conducting adhesive to protect the main body. At practice, the cover film is peeled off for attaching the conducting adhesive onto the circuit board 40 and then the base film is peeled off for attaching the chip 90 onto the conducting adhesive. The chip 90 and the circuit board 40 are hot-pressed for a period of time to solidify the insulating material 20 of the conducting adhesive, so that a structure that is conductive in the vertical direction and insulative in the horizontal direction is finally formed.

More particularly, the chip 90 includes the chip body 10 and the bump 30. The coupling areas 41 are disposed on the circuit board 40. After the chip 90 and the circuit board 40 are pressed together, the conducting particles 21 are distributed between the bump 30 and the coupling area 41 and simultaneously contact the bump 30 and the coupling area 41 to achieve the effect of being conductive in the vertical direction and insulative in the horizontal direction. However, the material cost is difficult to reduce since the bump 30 is made of materials having good conductivity such as gold, silver, copper, platinum, etc. Furthermore, because the area of the bump 30 for contacting the coupling area 41 via the conducting particles 21 is limited, the possibility to increase the conductivity is also limited.

### SUMMARY OF THE INVENTION

It is an object of the present invention to provide an integrated circuit chip for coupling to a circuit board, wherein the integrated circuit chip has improved conductivity.

It is another object of the present invention to provide an integrated circuit chip at a lower material cost.

It is another object of the present invention to provide an integrated circuit chip having increased bump surface area to enhance the electrical connection.

It is another object of the present invention to provide an integrated circuit chip manufacturing method to reduce the material cost.

The integrated circuit chip of the present invention has a chip body and at least one bump. The chip body has at least one conducting area on a surface thereof. The bump is formed on the conducting area. The bump includes a plurality of protrusions and at least one conducting material. The protrusions protrude out of the conducting area and are spaced apart from each other. The conducting material covers the protrusions and electrically connects the conducting area.

The protrusions are preferably made of photoresist. The conducting material preferably has a recess between the protrusions as the protrusions are covered by the conducting material. The integrated circuit chip is electrically coupled to a circuit board by means of a conducting adhesive having a plurality of conducting particles, wherein the width of the recess is at least 167% larger than the diameter of the conducting particle.

The integrated circuit manufacturing method includes: (A) providing a chip body, wherein the chip body has a conducting area on a surface thereof; (B) forming a plurality of protrusions on the chip body, wherein the plurality of protrusions protrude out of the conducting area and are spaced apart from each other; and (C) forming at least one conducting material, wherein the conducting material covers the protrusions and electrically connects the conducting area.

A packaging structure includes the integrated circuit chip of the present invention, a circuit board, and a conducting layer. The circuit board includes at least one coupling area. The conducting layer is disposed on the circuit board and includes a plurality of conducting particles. The integrated circuit chip is disposed on the conducting layer. The chip body has at least one conducting area on its surface, wherein the conducting area faces the conducting layer. The bump is formed on the conducting area. The bump includes a plurality of protrusions protruding out of the conducting area and being spaced apart from each other and at least one conducting material covering the protrusions and electrically connecting the conducting area, wherein the plurality of conducting particles are distributed between the conducting material and the coupling area to electrically connect the conducting material with the coupling area.

### BRIEF DESCRIPTION OF THE DRAWINGS

FIG. 1 is a schematic view of the prior art;

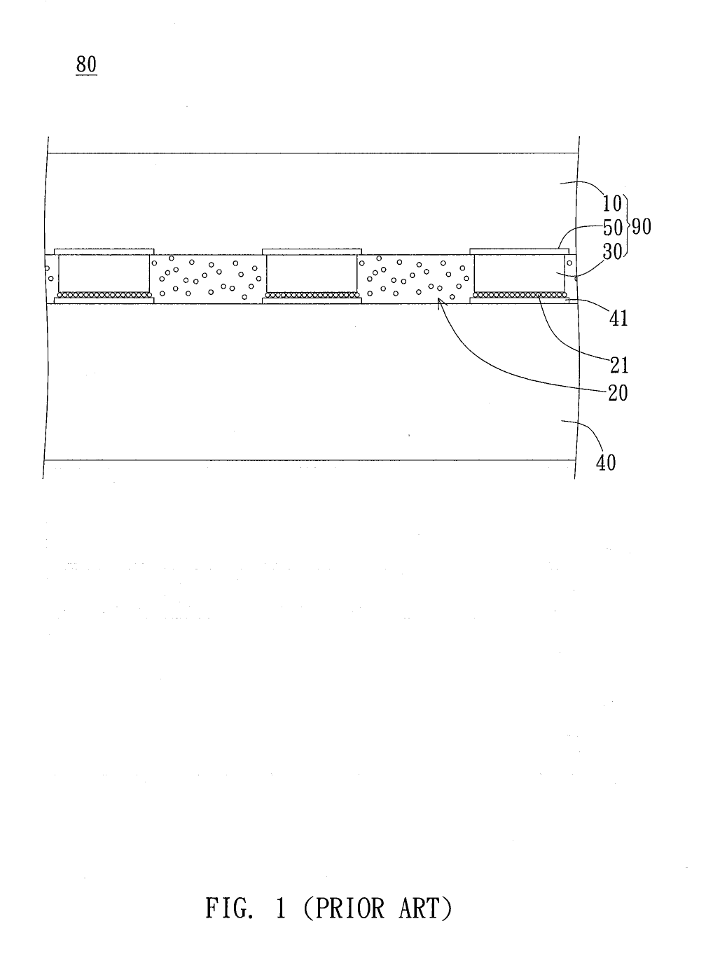

FIG. 2 is a schematic view of an embodiment of the present invention;

FIGS. 3A to 3C are schematic views of forming of the protrusions in an embodiment of the present invention;

FIG. 4A is a schematic view of another embodiment of the present invention;

FIG. 4B is a schematic view of a preferred embodiment of the present invention; and

FIG. 5 is a flowchart of the integrated circuit chip manufacturing method of the present invention.

### DETAILED DESCRIPTION OF THE PREFERRED EMBODIMENT

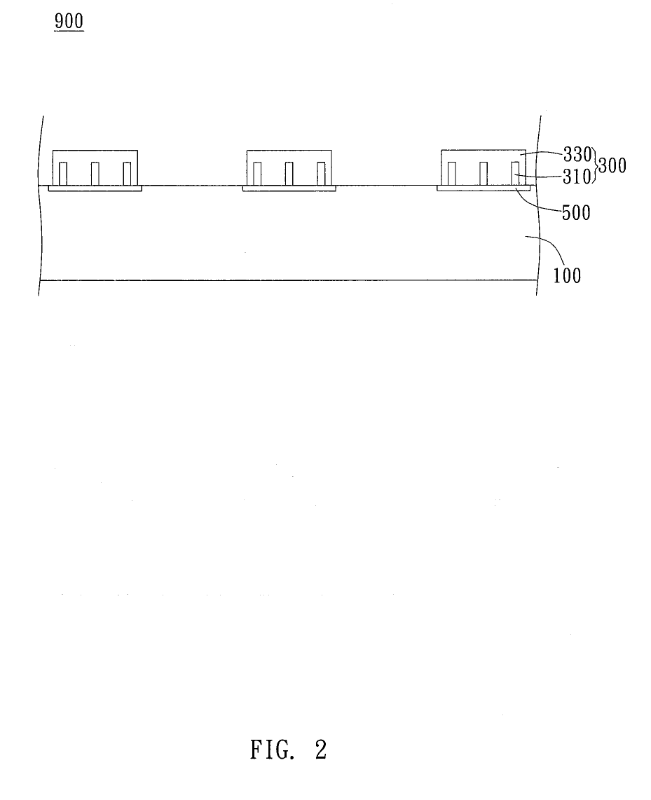

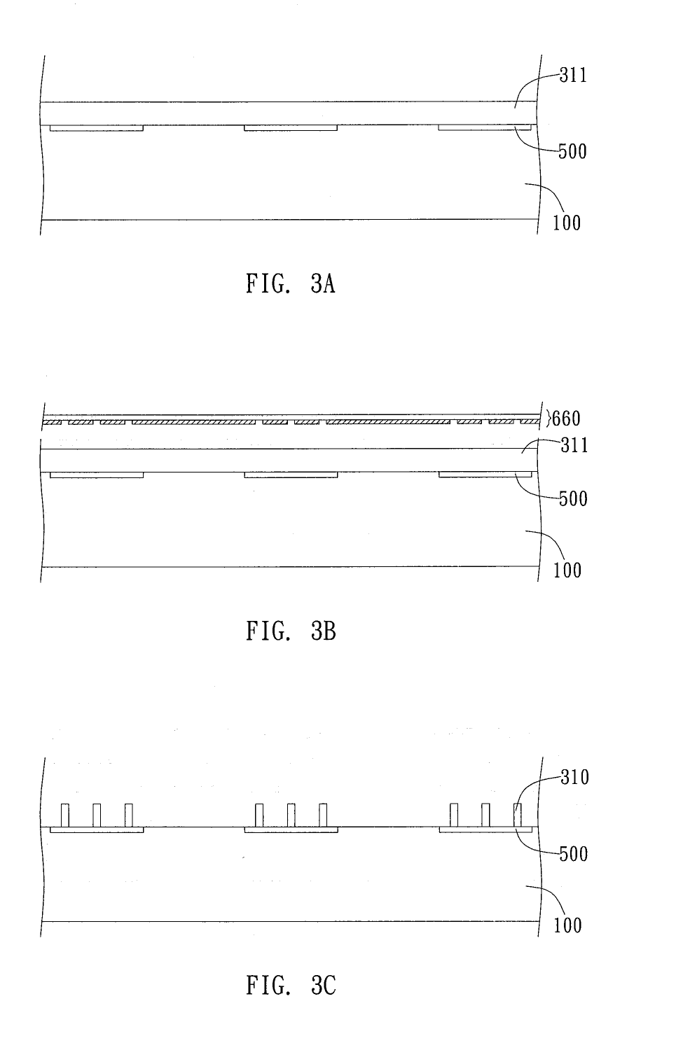

As shown in FIG. 2, in an embodiment, the integrated circuit chip 900 of the present invention has a chip body 100 and at least one bump 300. The chip body 100 has at least one conducting area 500 on a surface thereof. The bump 300 is formed on the conducting area 500. The bump 300 includes a plurality of protrusions 310 and at least one conducting material 330. The plurality of protrusions 310 protrude out of the conducting area 500 and are spaced apart from each other. That is, each protrusion 310 preferably stands alone on the conducting area 500. In a preferred embodiment, the protrusions 310 are made of photoresist. More particularly, the step of forming the protrusions includes covering the chip body 100 with a photoresist layer 311 as shown in FIG. 3A, exposing the photoresist layer 311 by using a photomask 666 as shown in FIG. 3B to harden the exposed portion of the photoresist layer 311, and developing the photoresist layer 311 to remove the unexposed portion to form the protrusions as shown in FIG. 3C.

As shown in FIG. 2, the conducting material 330 covers the protrusions 310 and electrically connects the conducting area 500. The conducting material 330 is made of materials having good conductivity such as gold, silver, copper, platinum, etc., wherein gold is preferred. In a preferred embodiment, the conducting material 330 is formed to cover the protrusions 310 by semiconductor processing steps such as deposition, photolithography, etching, polishing, etc. In different embodiments, however, the conducting material 330 can be formed by electroplating, electroless plating, screen printing, etc.

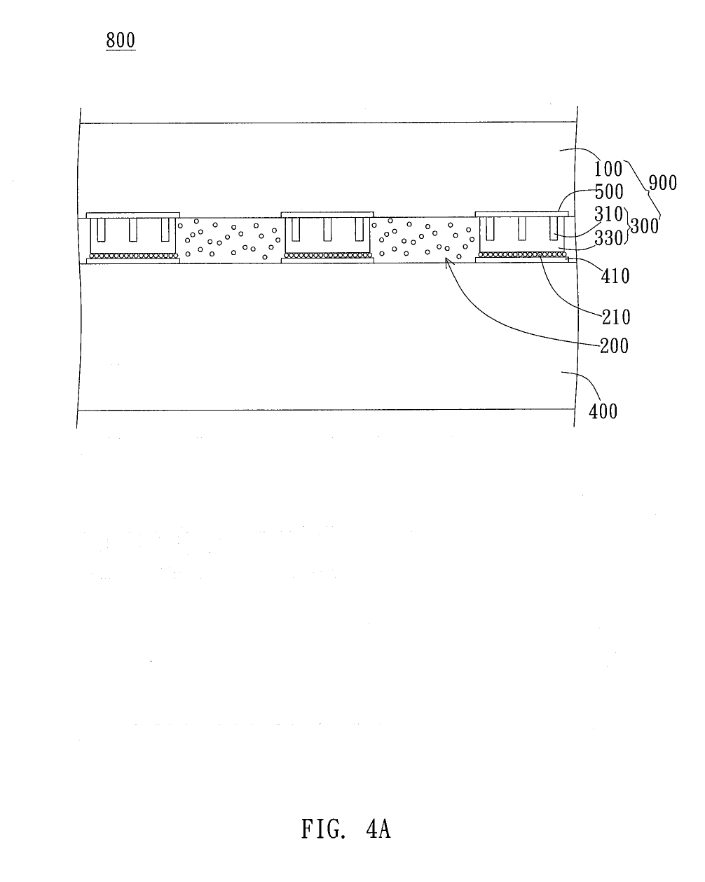

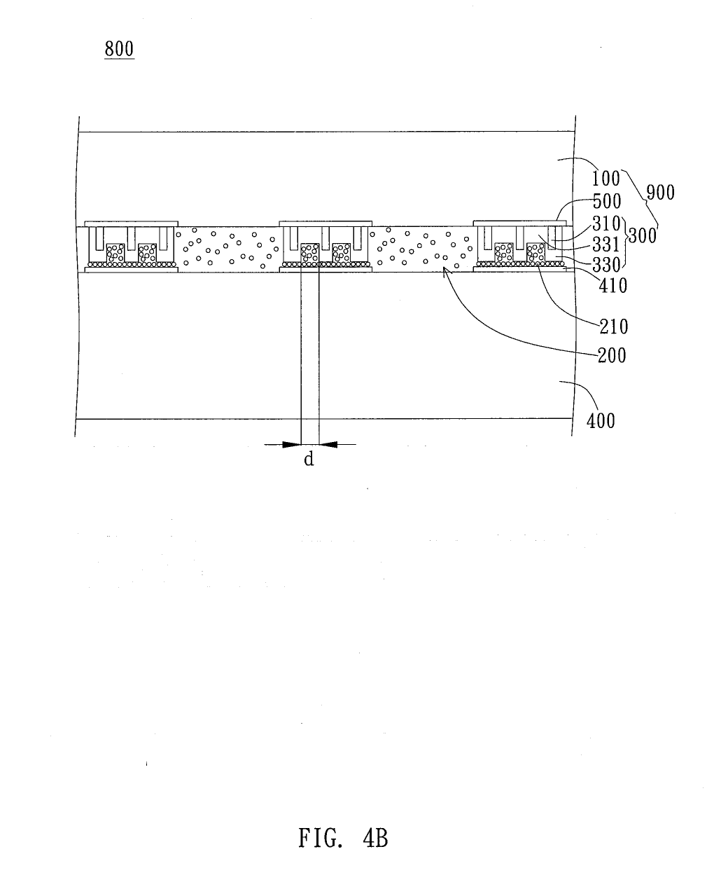

More particularly, as shown in FIG. 4A, the bump 300 is composed of the protrusions 311 and the conducting material 330 covering the protrusions 311. In other words, the protrusions 310 can be considered as the “skeleton” of the bump 300, wherein the conducting material 330 is the “muscle” covering the skeleton. Consequently, the amount of the conducting material 330 used in the bump 300 can be reduced to decrease the material cost of the integrated circuit chip 900.

In a preferred embodiment shown in FIG. 4B, the conducting material 330 has a recess 331 between the protrusions 310 as the protrusions 310 are covered by the conducting material 330. More particularly, the conductive material 330 has a concave-convex structure that can be formed by electroplating or chemical deposition. That is, the shape of the conductive material 330 is preferably conformal to the protrusions 310. In a preferred embodiment, the integrated circuit chip 900 is electrically coupled to the circuit board 400 by means of the conducting adhesive 200 having a plurality of conducting particles 210, wherein the width “d” of the recess is at least 167% larger than the diameter of the conducting particle 210. The conducting adhesive 200 is preferably a silver conductive adhesive, wherein the conducting particles are silver particles. The integrated circuit chip 900, the conducting adhesive 200, and the circuit board 400 are preferably connected by hot pressing.

More particularly, a packaging structure 800 is composed of the integrated circuit chip 900 of the present invention, a circuit board 400, and a conducting layer 200. The circuit board 400 includes at least one coupling area 410. The conducting layer 200 is disposed on the circuit board 400 and includes a plurality of conducting particles 210. The integrated circuit chip 900 is disposed on the conducting layer 200. The chip body 100 has at least one conducting area 500 on the surface, wherein the conducting area 500 faces the conducting layer 200. The bump 300 is formed on the conducting area 500. The bump 300 includes a plurality of protrusions 310 protruding out of the conducting area 500 and are spaced apart from each other. The conducting material 330 covers the protrusions 310 and electrically connects the conducting area 500. The plurality of conducting particles 210 are distributed between the conducting material 330 and the coupling area 410 and electrically connect the conducting material 330 with the coupling area 410. Because the conducting material 330 that covers the protrusions 310 has a concave-convex structure, the conductive particles 210 distributed in the recess of the conducting material 330 also electrically connect the conducting material 330 with the coupling area 410, the increase in area of the conducting material 330 for contacting with the conducting particles 210 is contributed to the increase in conductivity. Consequently, the conductivity of the integrated circuit chip 900 can be improved.

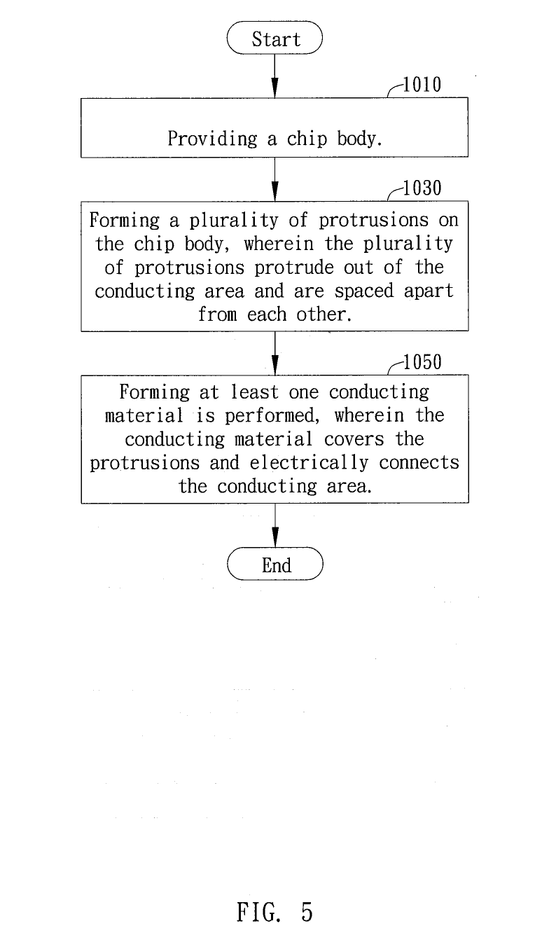

As shown in FIG. 5, the integrated circuit chip manufacturing method in a preferred embodiment of the present invention includes the following steps.

Step 1010, the step of providing a chip body is performed, wherein the chip body has at least one conducting area on the surface. More particularly, the chip body having at least one conducting area on the surface are formed by semiconductor processing steps such as deposition, photolithography, etching, polishing, etc.

Step 1030, the step of forming a plurality of protrusions on the chip body is performed, wherein the plurality of protrusions protrude out of the conducting area and are spaced apart from each other. More particularly, the protrusions 310 are formed of photoresist as shown in FIGS. 3A to 3C.

Step 1050, the step of forming at least one conducting material is performed, wherein the conducting material covers the protrusions and electrically connects the conducting area. More particularly, as shown in FIG. 2, the bump 300 is composed of the protrusions 310 and the conducting material 330 covering the protrusions 310.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. An integrated circuit chip, comprising:
a chip body having at least one conducting area on a surface thereof; and
at least one bump formed on the conducting area, the bump including:
a plurality of protrusions protruding out of the conducting area, wherein the protrusions are spaced apart from each other; and
at least one conducting material covering the protrusions, wherein the conducting material electrically connects the conducting area.

2. The integrated circuit chip of claim 1, wherein the protrusions are made of photoresist.

3. The integrated circuit chip of claim 1, wherein the conducting material has a recess between the protrusions.

4. The integrated circuit chip of claim 1, wherein the integrated circuit chip is further coupled to a circuit board by means of a conducting adhesive having a plurality of conducting particles, wherein the width of the recess is at least 167% larger than the diameter of the conducting particle.

5. An integrated circuit chip manufacturing method, comprising:
(A) providing a chip body, wherein the chip body has at least one conducting area on a surface thereof;
(B) forming a plurality of protrusions on the chip body, wherein the plurality of protrusions protrude out of the conducting area and are spaced apart from each other; and
(C) forming at least one conducting material, wherein the conducting material covers the protrusions and electrically connects the conducting area.

6. The integrated circuit chip manufacturing method of claim 5, wherein the step (B) includes using photoresist to form the plurality of protrusions.

7. The integrated circuit chip manufacturing method of claim 5, wherein the step (C) includes forming the conducting material with a recess between the protrusions.

8. A packaging structure, comprising:
a circuit board including at least one coupling area;
a conducting layer disposed on the circuit board, wherein the circuit board includes a plurality of conducting particles; and
an integrated circuit chip disposed on the conducting layer, the integrated circuit chip including:
a chip body having at least one conducting area on a surface thereof, wherein the conducting area faces the conducting layer; and
at least one bump formed on the conducting area, the bump including:
a plurality of protrusions protruding out of the conducting area, wherein the protrusions are spaced apart from each other; and
at least one conducting material covering the protrusions and electrically connecting the conducting area, wherein the plurality of conducting particles are distributed between the conducting material and the coupling area to electrically connect the conducting material with the coupling area.

9. The packaging structure of claim 8, wherein the conducting material has a recess between the protrusions, wherein the plurality of conducting particles are further distributed in the recess.

10. The packaging structure of claim 9, wherein the width of the recess is at least 167% larger than the diameter of the conducting particle.
